(19) United States
(12) Patent Application Publication
(10) Pub. No.: US 2026/0343898 A1
(43) Pub. Date: Oct. 29, 2026

(54) PHASE CHANGE MATERIAL-BASED MEMORY AND METHODS OF FORMING THE SAME

(71) Applicant: Taiwan Semiconductor Manufacturing Company, Ltd., Hsinchu (TW)

(72) Inventors: Chang-Chih Huang, Taichung (TW); Kuo-Pin Chang, Zhubei City (TW); Hung-Ju Li, Hsinchu City (TW); Yu-Wei Ting, Taipei City (TW); Kuo-Ching Huang, Hsinchu City (TW)

(73) Assignee: Taiwan Semiconductor Manufacturing Company, Ltd., Hsinchu (TW)

(21) Appl. No.: 19/190,901

(22) Filed: Apr. 28, 2025

(51) Int. Cl. H10B 63/10; H10B 63/00; H10N 70/00; H10N 70/20

(52) U.S. Cl. CPC H10B 63/10; H10B 63/22; H10N 70/011; H10N 70/231; H10N 70/8413; H10B 63/80; H10N 70/826; H10N 70/8828

(57) ABSTRACT

Semiconductor devices having phase change memory cells and method of forming and using the same are provided. The semiconductor devices include a phase change memory (PCM) layer formed of a phase change material configured to transition, upon heating, between a low-resistance state that includes a crystalline microstructure and a high-resistance state that includes an amorphous microstructure, a first liner layer disposed on a first end of the PCM layer and having a recessed portion that protrudes into the PCM layer, and a heating element having a distal end disposed within the recessed portion of the first liner layer such that the distal end is surrounded by the PCM layer with the first liner layer therebetween. The heating element is configured to perform heating of the PCM layer to transition the PCM layer between the low-resistance state and the high-resistance state.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 represents a perspective view of an isolated portion of a phase change material (PCM)-based memory cell of a semiconductor device in accordance with some embodiments;

FIG. 2 represents a cross-sectional view of the PCM-based memory cell of FIG. 1 in accordance with some embodiments;

FIG. 3 represents a cross-sectional view of a distal end of a heating element of the PCM-based memory cell of FIG. 1 that illustrates thermal transfer within the PCM-based memory cell in accordance with some embodiments;

FIG. 4 represents a cross-sectional view of the PCM-based memory cell of FIG. 1 illustrating a read operation while the PCM-based memory cell is in a low-resistance state in accordance with some embodiments;

FIG. 5 represents a cross-sectional view of the PCM-based memory cell of FIG. 1 illustrating a read operation while the PCM-based memory cell is in a high-resistance state in accordance with some embodiments;

FIG. 6 represents the total resistance of the PCM-based memory cell during the read operation of FIG. 4 in accordance with some embodiments;

FIG. 7 represents the total resistance of the PCM-based memory cell during the read operation of FIG. 5 in accordance with some embodiments;

FIGS. 8-14 represent cross-sectional views of a semiconductor device illustrating certain steps for fabricating PCM-based memory cells therein in accordance with some embodiments;

FIG. 15 represents a perspective view of an isolated portion of a phase change material (PCM)-based memory cell of another semiconductor device in accordance with some embodiments;

FIG. 16 represents a cross-sectional view of the PCM-based memory cell of FIG. 15 in accordance with some embodiments;

FIG. 17 represents a cross-sectional view of the PCM-based memory cell of FIG. 15 illustrating a read operation while the PCM-based memory cell is in a low-resistance state in accordance with some embodiments;

FIG. 18 represents a cross-sectional view of the PCM-based memory cell of FIG. 15 illustrating a read operation while the PCM-based memory cell is in a high-resistance state in accordance with some embodiments;

FIG. 19 represents the total resistance of the PCM-based memory cell during the read operation of FIG. 17 in accordance with some embodiments;

FIG. 20 represents the total resistance of the PCM-based memory cell during the read operation of FIG. 18 in accordance with some embodiments;

FIGS. 21-25 represent cross-sectional views of another semiconductor device illustrating certain steps for fabricating PCM-based memory cells therein in accordance with some embodiments; and

FIG. 26 includes a flowchart illustrating a method for fabricating and using a semiconductor device that includes a PCM-based memory cell in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Computing-in-Memory (CiM) is a technique that allows for the ability to tune resistance states within a memory device to enable in-memory computation. One way to implement CiM is to use a phase change material (PCM) (e.g., Ge₂Sb₂Te₅, GeSb, AgInSbTe) which is a type of material that is capable of existing in two different phase states. Specifically, a PCM may be in a crystalline state (i.e., Low-Resistance State, LRS) that has an ordered atomic structure, allowing for lower electrical resistance and higher conductivity, and an amorphous state (i.e., High-Resistance State, HRS) that has a disordered atomic structure, which increases electrical resistance and reduces conductivity. Data storage is achieved by switching between the HRS (logic 0) and the LRS (logic 1). In CiM applications, these resistance states may also be used to perform logical or arithmetic operations directly within the memory cells.

The transition between these phase states may be induced by heating the PCM using electrical pulses. For example, a short, high-intensity pulse may be used to melt and quench the PCM into the amorphous (HRS) state (a process referred to as RESET switching), whereas a longer, moderate-intensity pulse may be used to heat the PCM to a lower temperature than melting (e.g., just above the crystallization temperature), allowing gradual atomic rearrangement (recrystallization) into the crystalline (LRS) state (a process referred to as SET switching).

A PCM-based memory device may read data stored in a memory cell by measuring the electrical resistance thereof. For example, a small sensing voltage (much lower than the switching voltages) may be applied across the memory cell. This sensing voltage is configured to avoid altering the phase state of the PCM. A read circuit measures the current that flows through the memory cell in response to the applied voltage. The resistance of the memory cell determines the amount of current that flows. A sense amplifier may be used to compare the measured resistance to a predefined threshold, wherein the HRS is considered to be logic zero and the LRS is considered to be logic one. For Multi-Level Cells (MLC), where multiple intermediate resistance states exist due to partial recrystallization, multiple reference resistances may be used to differentiate stored values (e.g., 00, 01, 10, 11). The PCM-based memory device converts the measured resistance into a binary value (or multiple bits in MLC PCM) and sends the result to a processor.

In PCM-based memory devices, write power refers to the electrical power required to switch the PCM between its phase states. In general, write power relates to the energy efficiency and performance of PCM-based memory storage and CiM applications. Therefore, PCM-based memory cells need efficient heat dissipation since heat drives the phase change, and poor thermal isolation may lead to higher power consumption, that is, higher write power requirements.

Presented herein are embodiments of semiconductor devices or structures and of methods for forming semiconductor devices or structures with phase change material (PCM)-based memory cells. For convenience, the semiconductor devices and methods will be described herein in reference to PCM-based memory devices for CiM applications. However, the semiconductor devices and methods are not limited to this application and may be applicable to other devices that use PCMs.

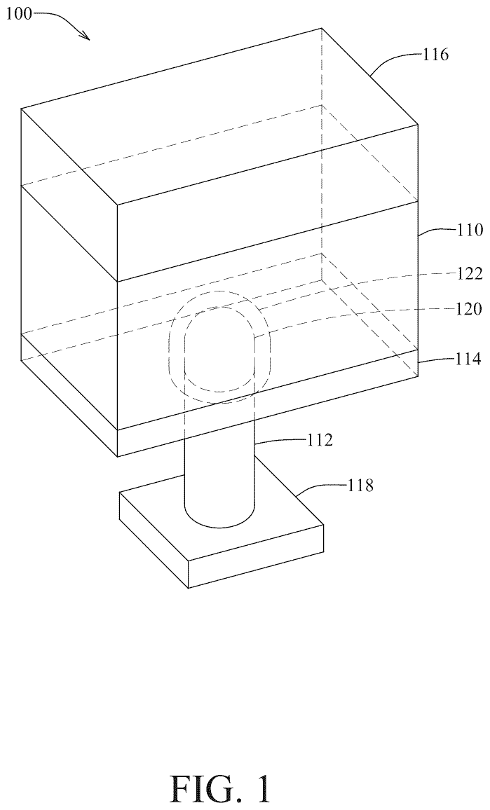

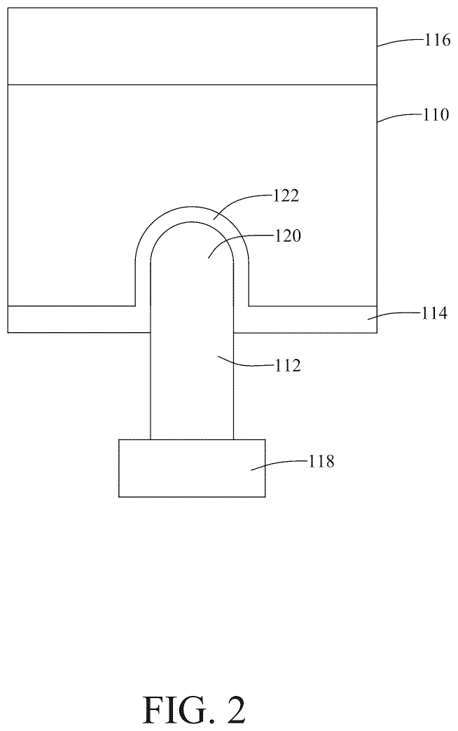

FIGS. 1 and 2 include isolated, perspective and cross-sectional views, respectively, of a portion of an exemplary PCM memory cell 100 (or simply the memory cell 100) in accordance with an embodiment. The memory cell 100 includes a PCM layer 110, a heating element 112, a liner layer 114, a read electrode 116 (e.g., first electrode), and a write electrode 118 (second electrode). The PCM layer 110 is configured to be programmable to change phase states to store data and/or perform in-memory computation. The PCM layer 110 may include various phase change materials such as, but not limited to, germanium telluride (GeTe), germanium antimony telluride (GeSbTe; GST), and doped-GST.

The heating element 112 is configured to receive electrical pulses to heat the PCM layer 110 and thereby transition between a crystalline state (i.e., Low-Resistance State, LRS) of the PCM layer 110 and an amorphous state (i.e., High-Resistance State, HRS) of the PCM layer 110. The heating element 112 may be formed of or include various materials such as, but not limited to, tungsten (W), titanium nitride (TiN), tantalum nitride (TaN), and carbon (C).

The read electrode 116 and the write electrode 118 are configured to have voltages applied thereto to perform reading and writing of the PCM layer 110, respectively. The read electrode 116 and the write electrode 118 may be formed of or include various materials, such as certain materials including, but not limited to, tungsten (W), tungsten nitride (WN), tantalum (Ta), and titanium nitride (TiN).

The liner layer 114 is configured to mitigate the resistance drift of the memory cell 100 when the PCM layer 110 is in the HRS state by effectively electrically shunting the amorphous region during a read operation and thereby reducing a likelihood of drift of the PCM layer 110. The liner layer 114 may be formed of or include various materials, such as certain high-resistance materials including, but not limited to, tantalum nitride (TaN), titanium nitride (TiN), tungsten nitride (WN), doped carbon (C), and doped nitrogen (N).

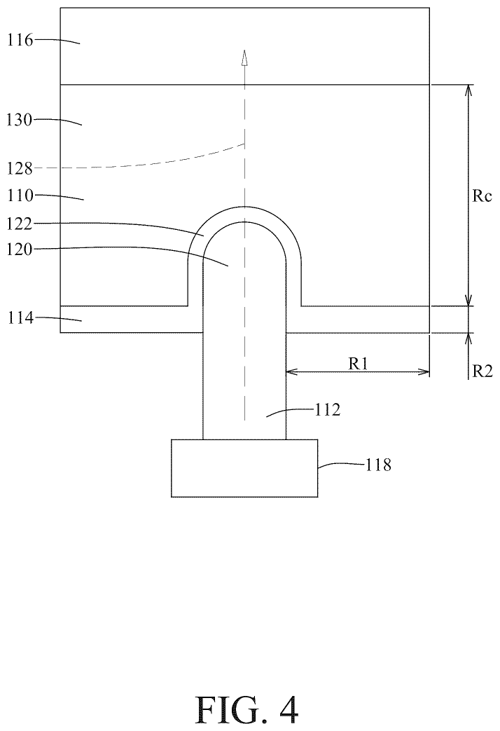

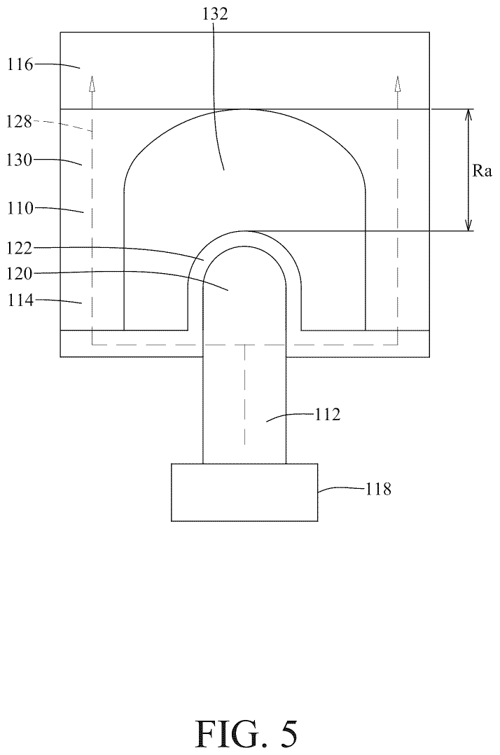

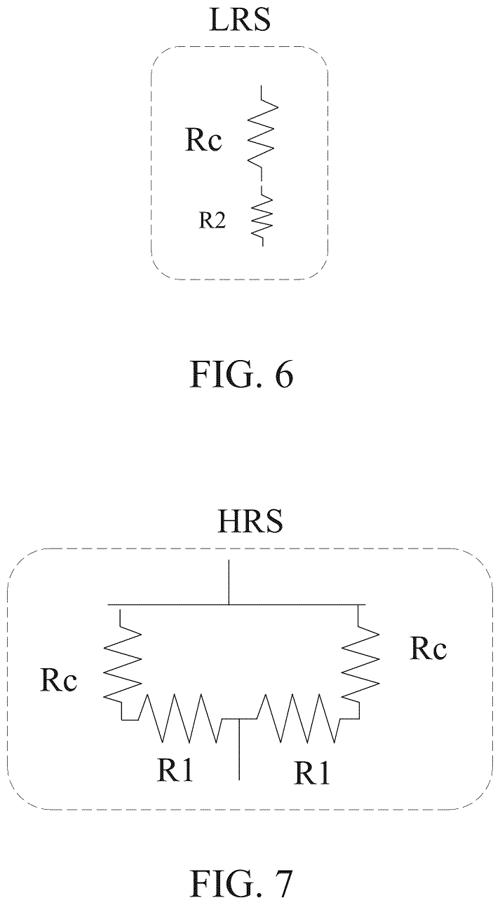

FIGS. 4 and 5 schematically illustrate read operations performed for different programmed states of the memory cell 100. For example, FIG. 4 schematically illustrates the LRS state of the PCM layer 110 in which an entirety of the PCM layer 110 comprises a crystalline region 130 having a crystalline microstructure, with no amorphous microstructure. FIG. 5 schematically illustrate the HRS state of the PCM layer 110 in which the PCM layer 110 comprises a combination of the crystalline region 130 having the crystalline microstructure and an amorphous region 132 having an amorphous microstructure. FIGS. 6 and 7 schematically represent resistance of the memory cell 100 during the read operations represented in FIGS. 4 and 5.

The read operations are performed by applying a read or sense pulse to the write electrode 118 to generate a read or sense current that flows to the read electrode 116. In FIGS. 4 and 5, the flow of current through the memory cell 100 is illustrated by dashed line arrows 128. In some embodiments, the liner layer 114 is configured to have a first resistance (R1 along length from center) and a second resistance (R2 along thickness) which are greater than a third resistance (Rc) of the crystalline region 130 of the PCM layer 110, but which is less than a fourth resistance (Ra) of the amorphous region 132 of the PCM layer 110 (e.g., Rc<R1/R2<Ra). In such examples, the total resistance in the LRS state is substantially a sum of the third resistance Rc of the crystalline region 130 of the PCM layer 110 and the second resistance R2 of a thickness of the liner layer 114, as represented in FIG. 6 (i.e., Rc+R2). In the HRS state in which the amorphous region 132 contacts the read electrode 116, the total resistance is substantially a sum of the first resistance R1 of a length of the liner layer 114 from the heating element 112 to the crystalline region 130 and the third resistance Rc of the crystalline region 130 divided by two, as represented in FIG. 7 (i.e., (R1+Rc)/2).

Certain existing PCM-based memory cells include a planar interface between the PCM layer (or the liner layer) and the heating element. In such arrangements, thermal loss may occur during programming of the memory cell from the heating element to a surrounding structures (e.g., an isolation layer). As such, this arrangement may require increased write power to transition between the phase states of the PCM layer due to the thermal loss.

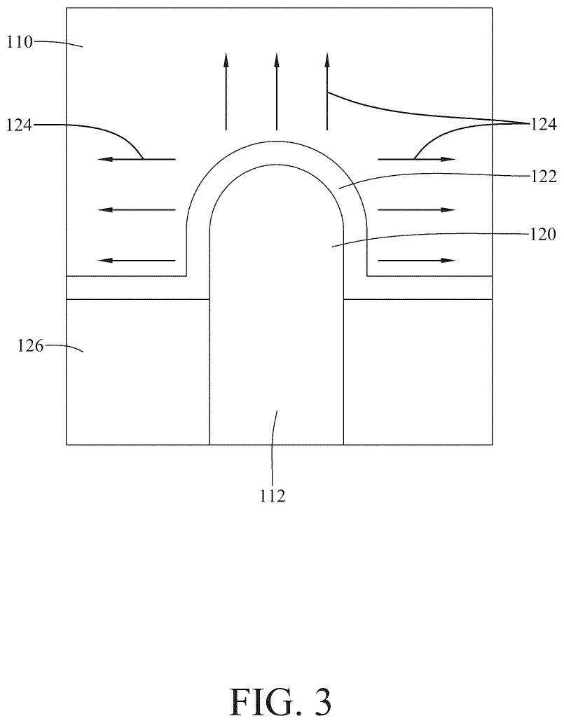

In contrast to these existing PCM-based memory cells, the memory cell 100 has a distal end of the heating element 112 that extends into the PCM layer 110, as represented in FIG. 1 and the cross-sectional view presented in FIGS. 2-5. This portion of the heating element 112, referred to herein as the embedded portion 120, is enclosed within and separated from the PCM layer 110 by a recessed portion 122 of the liner layer 114. Typically, the temperature of the heating element 112 during programming operations varies along the longitudinal length thereof, with a highest temperature occurring at the distal end of the heating element 112 adjacent to the PCM layer 110. Therefore, with this arrangement, a majority of the heat produced by the heating element 112 is transferred into the PCM layer 110 with little to no significant thermal loss to surrounding structures (e.g., an isolation layer), as represented in FIG. 3 (thermal transfer represented by arrows 124). The embedded portion 120 of the heating element 112 may have various shapes, including an elongated, cylindrical body with a rounded tip, a semi-spherical shaped body, or a convex shaped body. In some examples, the embedded portion 120 includes a sufficient portion of the heating element 112 to ensure that a majority of heat produced thereby is transferred to the PCM layer 110 during programming operations. In some examples, the embedded portion 120 extends into the PCM layer 110 by about 1 to 10 nanometers (nm).

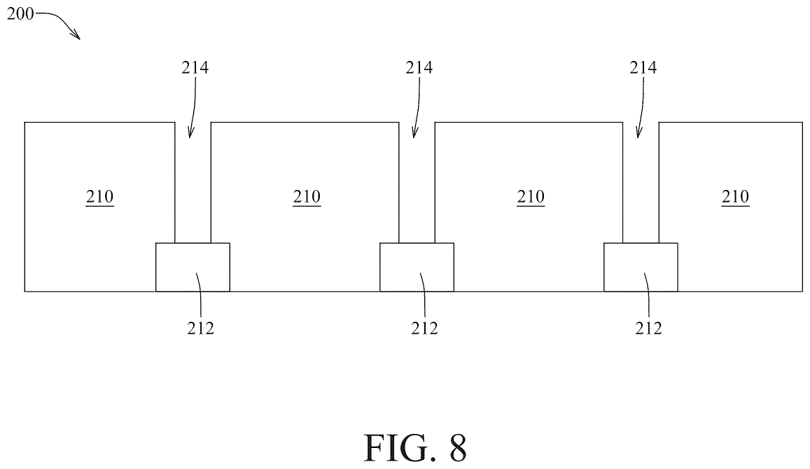

FIGS. 8-14 illustrate an exemplary method for forming PCM-based memory cells, such as the memory cell 100, in accordance with an example. In FIG. 8, a semiconductor structure is provided at step 200 that includes an isolation layer 210 with write electrodes 212 disposed therein. The isolation layer 210 may be patterned, for example, using photolithography and etching techniques to form trenches 214 in the isolation layer 210 to expose surfaces of the write electrodes 212. The isolation layer 210 may be formed of various materials such as, but not limited to, various oxides (e.g., SiO₂). The write electrodes 212 may be formed of or include various materials, such as certain materials including, but not limited to, tungsten (W), tungsten nitride (WN), tantalum (Ta), and titanium nitride (TiN).

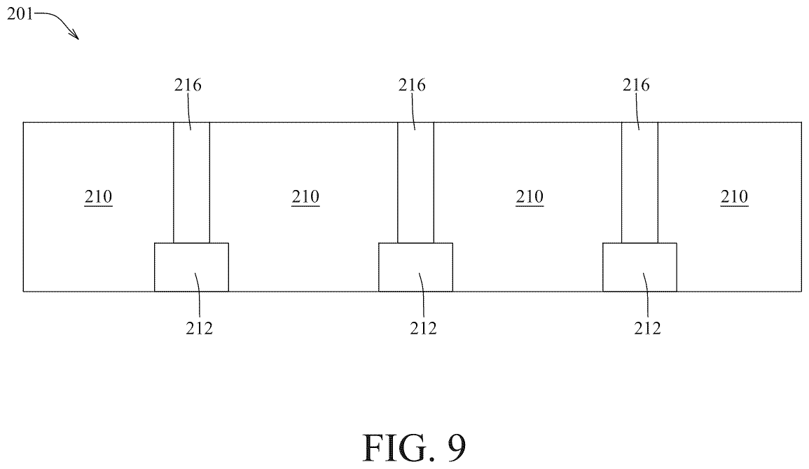

In FIG. 9, the trenches 214 are filled at step 201 to define heating elements 216 (e.g., the heating elements 112) which extend between the previously exposed surfaces of the write electrodes 212 and the exterior surface of the isolation layer 210. The heating elements 216 may be formed by, for example, various deposition and chemical mechanical polishing (CMP) processes. The heating elements 216 may be formed of or include various materials such as, but not limited to, tungsten (W), titanium nitride (TiN), tantalum nitride (TaN), and carbon (C).

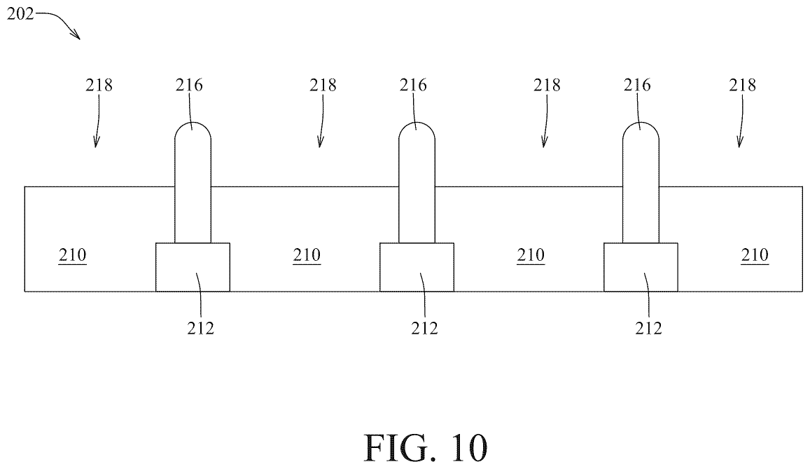

In FIG. 10, portions of the isolation layer 210 between the heating elements 216 are removed at step 202 to expose portions of the heating elements 216 that are intended to be embedded within a PCM layer. The isolation layer 210 may be removed using various photolithography and etching techniques.

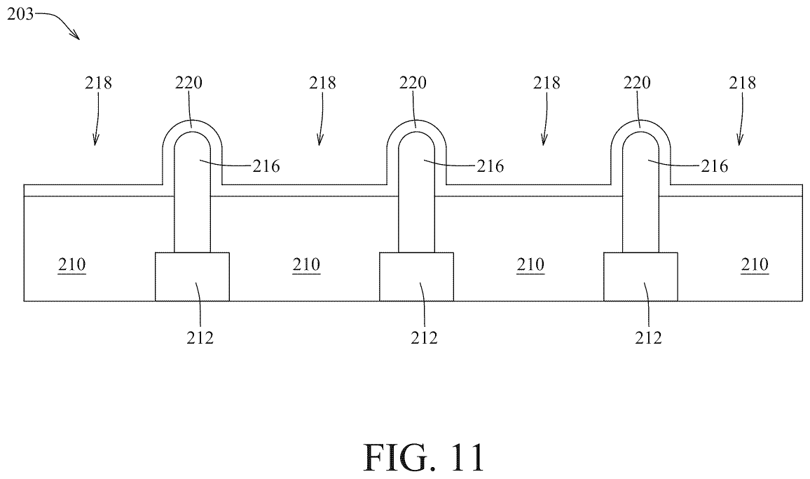

In FIG. 11, a liner layer 220 (e.g., the liner layer 114) may be formed over the exposed portions of the isolation layer 210 and the heating elements 216. The liner layer 220 may be formed using various deposition techniques. The liner layer 220 may be formed of or include various materials, such as certain high-resistance materials including, but not limited to, tantalum nitride (TaN), titanium nitride (TiN), tungsten nitride (WN), doped carbon (C), and doped nitrogen (N).

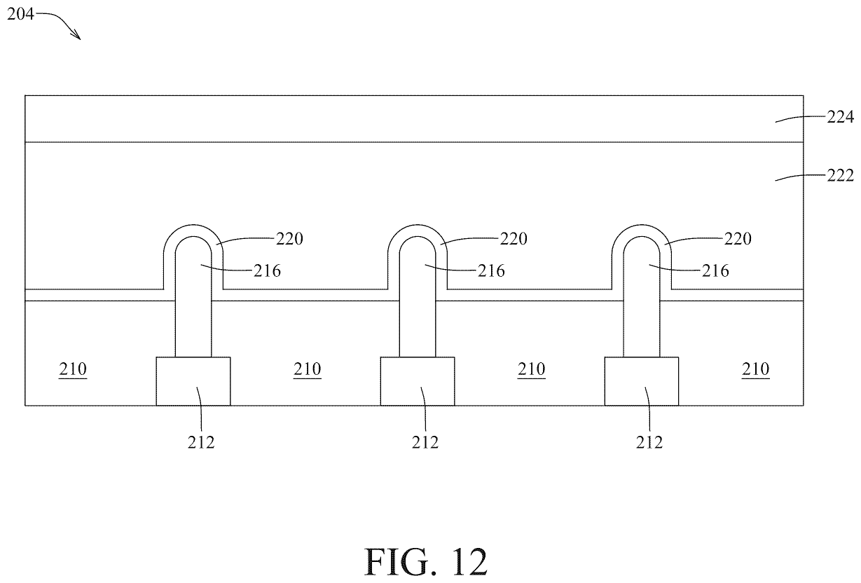

In FIG. 12, a PCM layer 222 (e.g., the PCM layer 110) may be formed over the liner layer 220, and a conductive layer 224 may be formed over the PCM layer 222 that is intended to define read electrodes. The PCM layer 222 and the conductive layer 224 may be formed by various deposition processes. The PCM layer 110 may include various phase change materials such as, but not limited to, germanium telluride (GeTe), germanium antimony telluride (GeSbTe; GST), and doped-GST. The conductive layer 224 may be formed of or include various materials, such as certain materials including, but not limited to, tungsten (W), tungsten nitride (WN), tantalum (Ta), and titanium nitride (TiN).

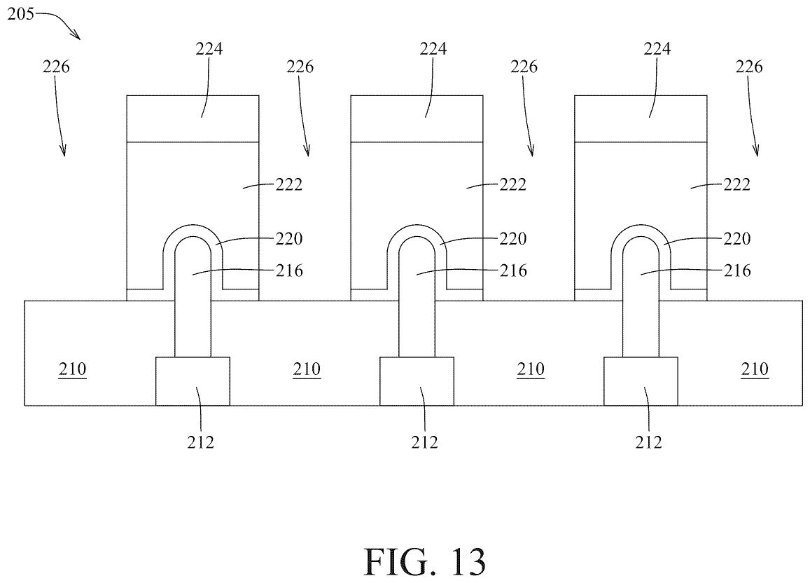

In FIG. 13, portions of the liner layer 220, the PCM layer 222, and the conductive layer 224 may be removed at step 205 to form trenches 226 and thereby define individual PCM-based memory cells. The portions of the liner layer 220, the PCM layer 222, and the conductive layer 224 may be removed using various photolithography and etching techniques.

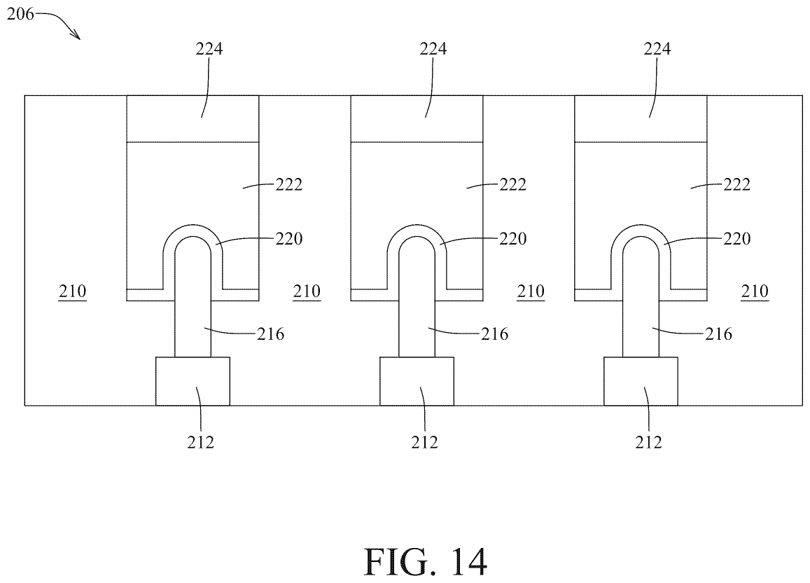

In FIG. 14, the trenches 226 between the individual PCM-based memory cells may be filled to dispose the isolation layer 210 therebetween and thereby isolate the individual PCM-based memory cells. The additional portion of the isolation layer 210 may be formed using various deposition techniques. Notably, the method illustrated in FIGS. 8-14 may be used to produce fewer or more PCM-based memory cells.

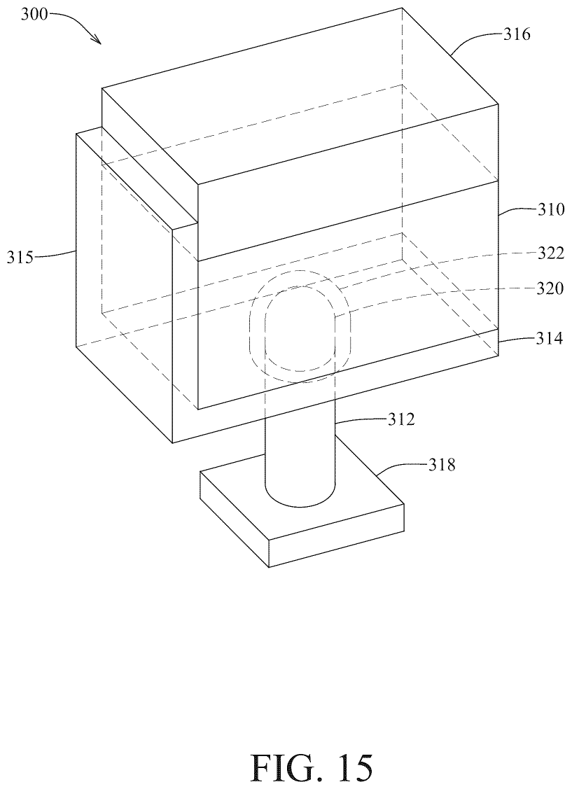

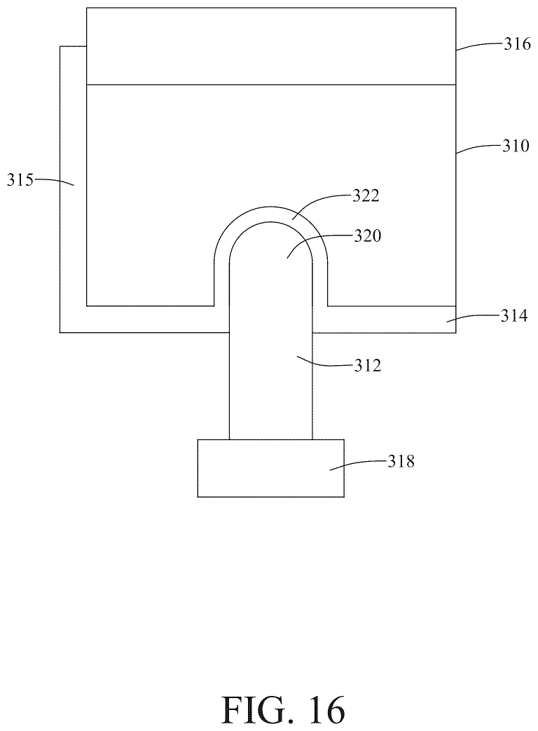

FIGS. 15 and 16 include isolated, perspective and cross-sectional views, respectively, of a portion of another exemplary PCM-based memory cell 300 in accordance with another embodiment. For convenience, consistent reference numbers are used throughout FIGS. 15 and 16 to identify the same or functionally related/equivalent elements, but with a numerical prefix (3) added to distinguish the particular example from other examples of the of the figures. In view of similarities between the examples, the following discussion of FIGS. 15 and 16 will focus primarily on aspects of the examples that differ from the first example in some notable or significant manner. Other aspects of the example not discussed in any detail can be, in terms of structure, function, materials, etc., essentially as was described for the first example of FIGS. 1 and 2.

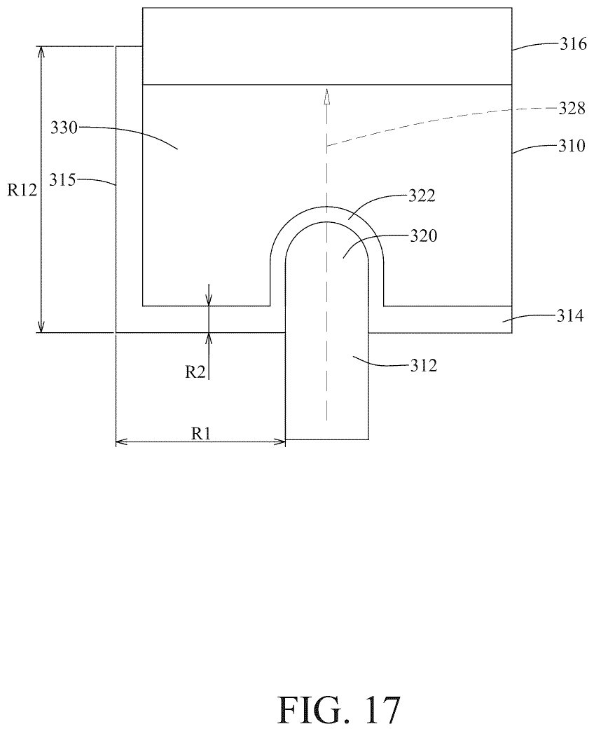

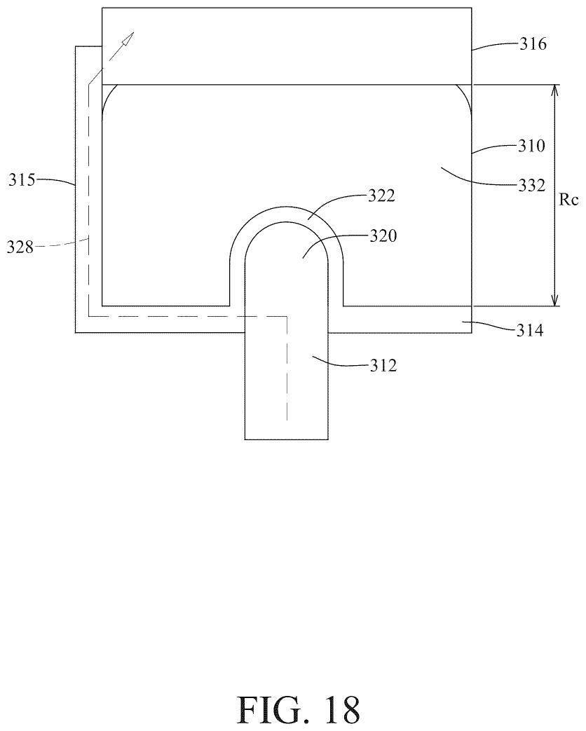

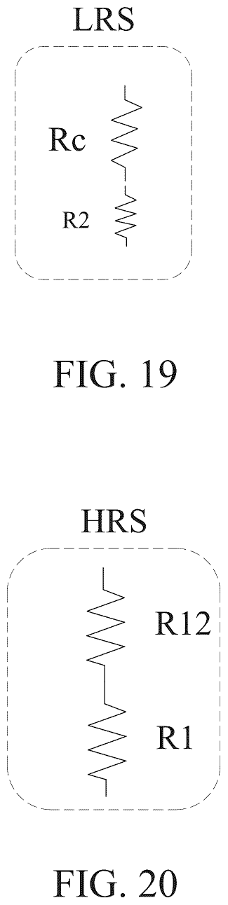

The PCM-based memory cell 300 includes a PCM layer 310, a heating element 312, a liner layer 314, a read electrode 316, and a write electrode 318. A distal end (e.g., the embedded portion 320) of the heating element 312 extends into the PCM layer 310 and is enclosed within and separated from the PCM layer 310 by a recessed portion 322 of the liner layer 314. The PCM layer 310 is configured to be programmable to change phase states to store data and/or perform in-memory computation. The PCM-based memory cell 300 is substantially the same as the memory cell 100, except that the liner layer 314 includes an extension portion 315 along a side of the PCM layer 310 and contacts the read electrode 316. Notably, the memory cell 300 may include the extension portion 315 on any side of the PCM layer 310, and may optionally include the extension portion 315 on more than one side of the PCM layer 310. This arrangement may reduce a likelihood of drift of the PCM layer 310 by providing an electrical path that bypasses an amorphous region while in the HRS state. For example, FIGS. 17 and 18 schematically illustrate read operations performed for different programmed states of the PCM-based memory cell 300 including the LRS state (FIG. 17) in which an entirety of the PCM layer 310 comprises a crystalline region 330 having a crystalline microstructure, with no amorphous microstructure, and the HRS state (FIG. 18) in which an entirety of the PCM layer 310 comprises an amorphous region 332 having an amorphous microstructure. FIGS. 19 and 20 schematically represent resistance of the PCM-based memory cell 300 during the read operations represented in FIGS. 17 and 18. In FIGS. 17 and 18, the flow of current through the memory cell 300 is illustrated by dashed line arrows 328.

In some embodiments, the liner layer 314 is configured to have a resistance (R1/R2) which is greater than a resistance (Rc) of the crystalline region 330 of the PCM layer 310, but which is less than a resistance (Ra) of the amorphous region 332 of the PCM layer 310 (e.g., Rc<R1/R2/R12<Ra). In such examples, the resistance in the LRS state is substantially a sum of the resistance Rc of the crystalline region 330 of the PCM layer 310 and the resistance R2 of the thickness of the liner layer 314, as represented in FIG. 19 (i.e., Rc+R2). In the HRS state, the resistance is substantially a sum of a resistance R1 along the length of the liner layer 314 from the heating element 312 to the end of the PCM layer 310 and a resistance R12 along the extension portion 315 of the liner layer 314 along the side of the PCM layer 310, as represented in FIG. 20 (i.e., R1+R12).

FIGS. 8-12 and 21-25 illustrate an exemplary method for forming a PCM-based memory cell, such as the PCM-based memory cell 300, in accordance with an example. First, the method includes the steps 200-204 described in reference to FIGS. 8-12 as described previously.

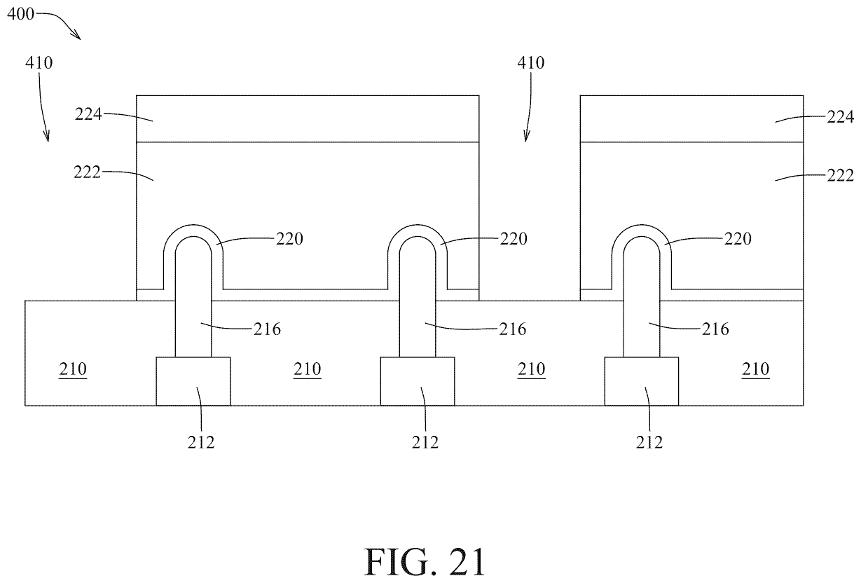

In FIG. 21, portions of the liner layer 220, the PCM layer 222, and the conductive layer 224 may be removed at step 400 to form trenches 410. The portions of the liner layer 220, the PCM layer 222, and the conductive layer 224 may be removed using various photolithography and etching techniques.

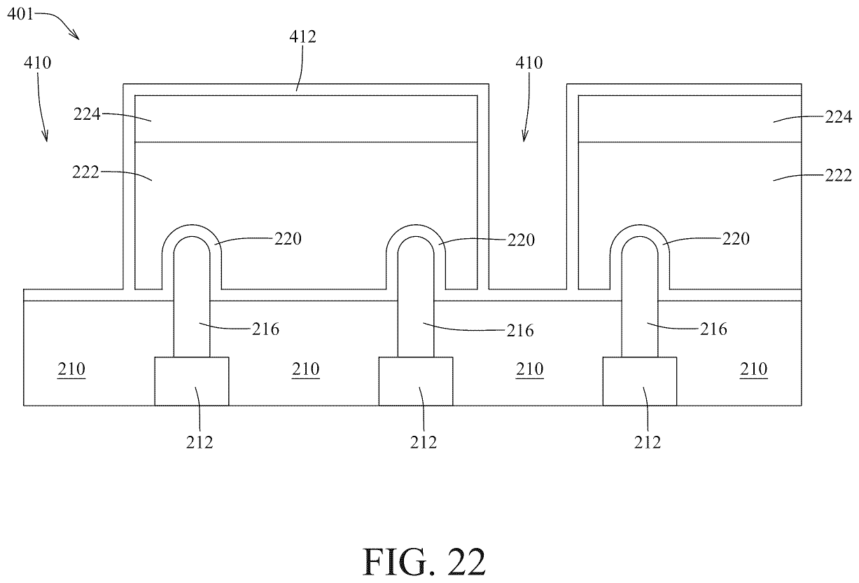

In FIG. 22, a second liner layer 412 may be formed at step 401 on the base and sidewalls of the trenches 410 and the conductive layer 224. The second liner layer 412 may be formed using various deposition techniques. The second liner layer 412 may be formed of or include various materials, such as certain high-resistance materials including, but not limited to, tantalum nitride (TaN), titanium nitride (TiN), tungsten nitride (WN), doped carbon (C), and doped nitrogen (N). In some examples, the second liner layer 412 may be formed of the same material as the liner layer 220.

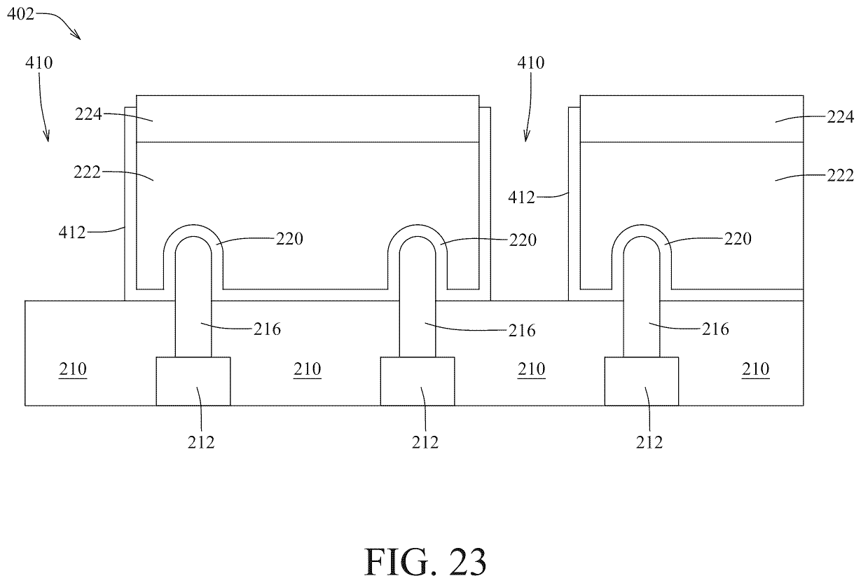

In FIG. 23, portions of the second liner layer 412 may be removed at step 402 from the base of the trenches 410 and from the outermost surfaces of the conductive layer 224. The portions of the second liner layer 412 may be removed using various photolithography and etching techniques.

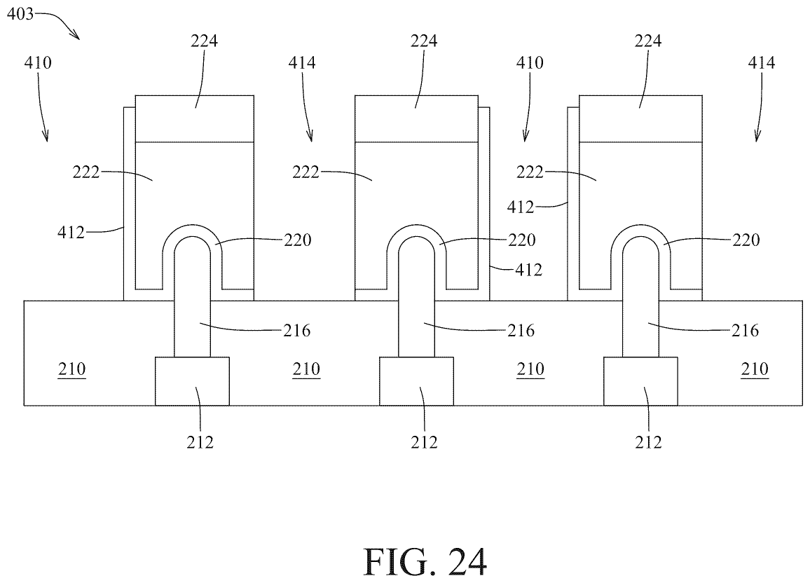

In FIG. 24, portions of the second liner layer 412, the PCM layer 222, and the conductive layer 224 may be removed at step 403 to form trenches 414 and thereby define individual PCM-based memory cells. The portions of the liner layer 220, the PCM layer 222, and the conductive layer 224 may be removed using various photolithography and etching techniques.

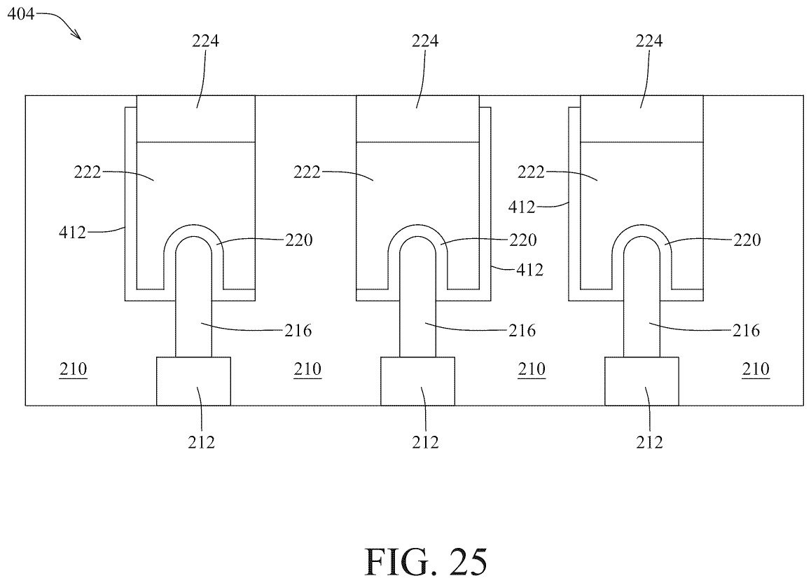

In FIG. 25, the trenches 410, 414 between the individual PCM-based memory cells may be filled at step 404 to extend the isolation layer 210 therebetween and thereby isolate the individual PCM-based memory cells. The additional portion of the isolation layer may be formed using various deposition techniques. Notably, the method illustrated in FIGS. 8-12 and 21-25 may be used to produce fewer or more PCM-based memory cells.

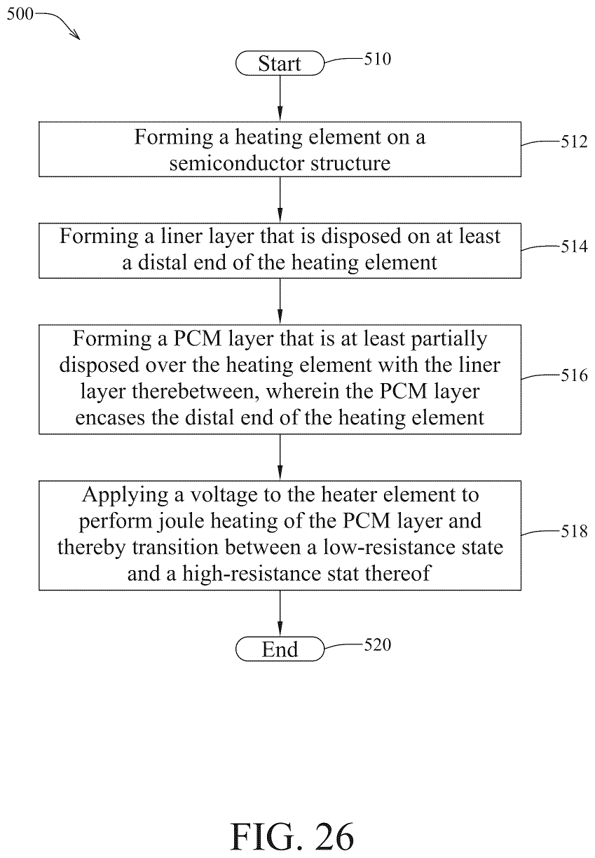

With reference now to FIG. 26 and with continued reference to FIGS. 1-25, a flowchart provides a method 500 for forming and using a PCM-based device, in accordance with various examples. In one example, the method 500 may start at 510. At 512, the method 500 may include forming a heating element on a semiconductor structure. At 514, the method 500 may include forming a liner layer that is disposed on at least a distal end of the heating element. At 516, the method 500 may include forming a PCM layer that is at least partially disposed over the heating element with the liner layer therebetween, wherein the PCM layer encases the distal end of the heating element. At 518, the method 500 may include operating the PCM-based device to program a PCM-based memory cell thereof, that is, transition the PCM layer between an LRS and an HRS, by joule heating the PCM layer with the heating element (i.e., passing an electrical current through the heating element to produce thermal energy due to resistance of the heating element), wherein a majority of the heat generated by the distal end of the heating element is conducted into the PCM layer with relatively little to no thermal loss to adjacent structures. The method 500 may end at 520.

The present disclosure therefore provides semiconductor devices and methods for forming semiconductor devices that includes a PCM layer with at least a portion of a heating element embedded therein. With such arrangement, a majority of the heat generated by the distal end of the heating element may be conducted into the PCM layer with relatively little to no thermal loss. This may reduce the energy required for read and/or write operations. In some examples, the semiconductor devices disclosed herein may have a write power of about 10 to 20 percent less than existing PCM-based memory devices that have a planar interface between the heating element and the PCM layer.

In accordance with an embodiment, a semiconductor device is provided that includes a phase change memory (PCM) layer formed of a phase change material configured to transition, upon heating, between a low-resistance state that includes a crystalline microstructure and a high-resistance state that includes an amorphous microstructure, a first liner layer disposed on a first end of the PCM layer and having a recessed portion that protrudes into the PCM layer, and a heating element having a distal end disposed within the recessed portion of the first liner layer such that the distal end is surrounded by the PCM layer with the first liner layer therebetween, wherein the heating element is configured to perform heating of the PCM layer to transition the PCM layer between the low-resistance state and the high-resistance state.

In accordance with another embodiment, a semiconductor device that includes a phase change memory (PCM) layer formed of a phase change material configured to transition, upon heating, between a low-resistance state that includes a crystalline microstructure and a high-resistance state that includes an amorphous microstructure, a first liner layer disposed on a first end of the PCM layer and having a recessed portion that protrudes into the PCM layer, a heating element having a distal end disposed within the recessed portion of the first liner layer such that the distal end is surrounded by the PCM layer with the first liner layer therebetween, wherein the heating element is configured to perform heating of the PCM layer to transition the PCM layer between the low-resistance state and the high-resistance state, an electrode disposed on a second end of the PCM layer opposite the first end, and a second liner layer disposed on a side of the PCM layer to extend between and connect the first liner layer and the electrode.

In accordance with yet another embodiment, a method is provided for forming a semiconductor device. The method includes forming a heating element on a semiconductor structure, forming a first liner layer disposed on at least a distal end of the heating element, and forming a phase change memory (PCM) layer of a phase change material over the first liner layer such that the PCM layer encases at least the distal end of the heating element with the first liner layer therebetween. The phase change material is configured to transition, upon heating, between a low-resistance state that includes a crystalline microstructure and a high-resistance state that includes an amorphous microstructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a phase change memory (PCM) layer formed of a phase change material configured to transition, upon heating, between a low-resistance state that includes a crystalline microstructure and a high-resistance state that includes an amorphous microstructure;
a first liner layer disposed on a first end of the PCM layer and having a recessed portion that protrudes into the PCM layer; and
a heating element having a distal end disposed within the recessed portion of the first liner layer such that the distal end is surrounded by the PCM layer with the first liner layer therebetween, wherein the heating element is configured to perform heating of the PCM layer to transition the PCM layer between the low-resistance state and the high-resistance state.

2. The semiconductor device of claim 1, wherein the crystalline microstructure of the PCM layer has a first resistance, the amorphous microstructure of the PCM layer has a second resistance, and the first liner layer has a third resistance, wherein the third resistance is greater than the first resistance and less than the second resistance.

3. The semiconductor device of claim 1, wherein the distal end of the heating element has a convex shape.

4. The semiconductor device of claim 1, further comprising a first electrode in operable contact with the heating element and configured to apply a voltage thereto for joule heating of the PCM layer, and a second electrode disposed on a second end of the PCM layer opposite the first end, wherein the second electrode is separated from the first liner layer by the PCM layer.

5. The semiconductor device of claim 1, further comprising an electrode disposed on a second end of the PCM layer opposite the first end, and a second liner layer disposed on a side of the PCM layer to extend between and connect the first liner layer and the electrode.

6. The semiconductor device of claim 5, wherein the crystalline microstructure of the PCM layer has a first resistance, the amorphous microstructure of the PCM layer has a second resistance, the first liner layer has a third resistance, and the second liner layer has a fourth resistance, wherein the third resistance and the fourth resistance are both greater than the first resistance and both less than the second resistance.

7. A semiconductor device, comprising:
a phase change memory (PCM) layer formed of a phase change material configured to transition, upon heating, between a low-resistance state that includes a crystalline microstructure and a high-resistance state that includes an amorphous microstructure;
a first liner layer disposed on a first end of the PCM layer and having a recessed portion that protrudes into the PCM layer;
a heating element having a distal end disposed within the recessed portion of the first liner layer such that the distal end is surrounded by the PCM layer with the first liner layer therebetween, wherein the heating element is configured to perform heating of the PCM layer to transition the PCM layer between the low-resistance state and the high-resistance state;
an electrode disposed on a second end of the PCM layer opposite the first end; and
a second liner layer disposed on a side of the PCM layer to extend between and connect the first liner layer and the electrode.

8. The semiconductor device of claim 7, wherein the crystalline microstructure of the PCM layer has a first resistance, the amorphous microstructure of the PCM layer has a second resistance, the first liner layer has a third resistance, and the second liner layer has a fourth resistance, wherein the third resistance and the fourth resistance are both greater than the first resistance and both less than the second resistance.

9. The semiconductor device of claim 7, wherein the distal end of the heating element has a convex shape.

10. The semiconductor device of claim 7, wherein the phase change material includes GeTe, GeSbTe, or doped GeSbTe, wherein the first liner layer includes TaN, TiN, WN, doped C, or doped N, wherein the heating element includes W, TiN, TaN, or C.

11. A method, comprising:
forming a heating element on a semiconductor structure;
forming a first liner layer disposed on at least a distal end of the heating element; and
forming a phase change memory (PCM) layer of a phase change material over the first liner layer such that the PCM layer surrounds at least the distal end of the heating element with the first liner layer therebetween, wherein the phase change material is configured to transition, upon heating, between a low-resistance state that includes a crystalline microstructure and a high-resistance state that includes an amorphous microstructure.

12. The method of claim 11, wherein the crystalline microstructure of the PCM layer has a first resistance, the amorphous microstructure of the PCM layer has a second resistance, and the first liner layer has a third resistance, wherein the third resistance is greater than the first resistance and less than the second resistance.

13. The method of claim 11, wherein forming the heating element include forming the distal end of the heating element to have a convex shape.

14. The method of claim 11, further comprising forming a first electrode to be in operable contact with the heating element and configured to apply a voltage thereto for joule heating of the PCM layer on a first end thereof, and forming a second electrode disposed on a second end of the PCM layer opposite the first end, wherein the second electrode is separated from the first liner layer by the PCM layer.

15. The method of claim 11, further comprising forming an electrode disposed on the PCM layer opposite the first liner layer, and forming a second liner layer disposed on a side of the PCM layer to extend between and connect the first liner layer and the electrode.

16. The method of claim 15, wherein the crystalline microstructure of the PCM layer has a first resistance, the amorphous microstructure of the PCM layer has a second resistance, the first liner layer has a third resistance, and the second liner layer has a fourth resistance, wherein the third resistance and the fourth resistance are both greater than the first resistance and both less than the second resistance.

17. The method of claim 11, further comprising forming an isolation layer that surrounds and isolates the heating element, the first liner layer, and the PCM layer to define a PCM-based memory cell.

18. The method of claim 11, wherein the distal end of the heating element is aligned with a center of the PCM layer.

19. The method of claim 11, further comprising applying a voltage to the heating element to perform joule heating of the PCM layer and thereby transition between the low-resistance state and the high-resistance state.

20. The method of claim 11, forming the heating element, the first liner layer, and the PCM layer such that, upon heating the PCM layer with the heating element, a majority of heat generated by the distal end of the heating element is conducted directly into the PCM layer with relatively little to no thermal loss.
